(19) United States
(12) Patent Application Publication
(10) Pub. No.: US 2022/0128746 A1
(43) Pub. Date: Apr. 28, 2022

(54) APODIZED GRATING COUPLER

(71) Applicant: Facebook Technologies, LLC, Menlo Park, CA (US)

(72) Inventors: Wanli Chi, Sammamish, WA (US); Yang Yang, Redmond, WA (US); Dominic Meiser, Issaquah, WA (US); Wai Sze Tiffany Lam, Redmond, WA (US)

(21) Appl. No.: 17/125,622

(22) Filed: Dec. 17, 2020

Related U.S. Application Data
(60) Provisional application No. 63/104,715, filed on Oct. 23, 2020.

(51) Int. Cl. G02B 5/18; F21V 8/00; G02B 27/00; G03F 7/00

(52) U.S. Cl. CPC G02B 5/1866; G02B 6/0016; G02B 6/0035; G03F 7/0005; G02B 27/0018; G02B 5/1842; G02B 27/0081; G02B 5/1857

(57) ABSTRACT

An optical coupler includes a plurality of volume gratings in a substrate. The gratings include an array of fringes extending along length and thickness dimensions of the substrate. A difference between a refractive index of the fringes and a refractive index of the substrate depends on a depth coordinate along the thickness dimension of the substrate. A dependence of the difference on the depth coordinate has a bell-shaped function which suppresses ghost image formation due to optical crosstalk between gratings of neighboring spatial pitches.

### REFERENCE TO RELATED APPLICATION

This application claims priority from U.S. Provisional Application No. 63/104,715, filed on Oct. 23, 2020, entitled “APODIZED GRATING COUPLER” and incorporated herein by reference in its entirety.

### TECHNICAL FIELD

The present disclosure relates to optical devices, and in particular to optical couplers and gratings, and lightguides with grating couplers

### BACKGROUND

Visual displays are used to provide information to viewer(s) including still images, video, data, etc. Visual displays have applications in diverse fields including entertainment, education, engineering, science, professional training, advertising, to name just a few examples. Some visual displays, such as TV sets, display images to several users, and some visual display systems are intended for individual users.

Head mounted displays (HMD), near-eye displays (NED), and the like are used for displaying content to individual users. The content displayed by HMD/NED includes virtual reality (VR) content, augmented reality (AR) content, mixed reality (MR) content, etc. The displayed VR/AR/MR content can be three-dimensional (3D) to enhance the experience and, for AR/MR applications, to match virtual objects to real objects observed by the user.

Compact display devices are desired for head-mounted displays. Because a display of HMD or NED is usually worn on the head of a user, a large, bulky, unbalanced, and/or heavy display device would be cumbersome and may be uncomfortable for the user to wear. Compact display devices require compact optical components such as lightguides, gratings, lenses, etc., that would provide high optical throughput, high degree of image clarity and fidelity, no image ghosting, low optical aberrations, etc.

### BRIEF DESCRIPTION OF THE DRAWINGS

Exemplary embodiments will now be described in conjunction with the drawings, in which:

FIGS. 1A and 1B are side cross-sectional views of pupil-replicating lightguides having input and output volume gratings, the pupil-replicating lightguide of FIG. 1A being configured to provide a different portion of field of view (FOV) than the pupil-replicating lightguide of FIG. 1B;

FIG. 2 is a side cross-sectional views of a pupil-replicating lightguide having multiplexed volume gratings for a broader FOV;

FIG. 3A is an angular dependence of diffraction wavelengths of a plurality of sparsely spaced volume gratings usable in the pupil-replicating lightguide of FIG. 2;

FIG. 3B is an angular dependence of diffraction efficiency of the plurality of volume gratings of FIG. 3A;

FIG. 3C is an angular dependence of diffraction wavelengths of a plurality of densely spaced volume gratings usable in the pupil-replicating lightguide of FIG. 2;

FIG. 3D is an angular dependence of diffraction efficiency of the plurality of volume gratings of FIG. 3C;

FIG. 3E is a magnified view of the angular dependence of FIG. 3C superimposed with local diffraction efficiency plots for two neighboring volume gratings of FIG. 3C;

FIG. 3F is a side cross-sectional view of a pupil-replicating lightguide illustrating optical crosstalk;

FIG. 4A is an angular reflectivity plot of two non-apodized volume gratings in the pupil-replicating lightguide of FIG. 2;

FIG. 4B is an angular reflectivity plot of two apodized volume gratings in the pupil-replicating lightguide of FIG. 2;

FIG. 5 is a three-dimensional view of a grating-based optical coupler usable in a lightguide disclosed herein;

FIG. 6A shows example apodization profiles of volume gratings in the optical coupler of FIG. 5;

FIG. 6B is a graph of refractive index contrast amplitude of different volume gratings in some embodiments of the optical coupler of FIG. 5;

FIG. 7 is a schematic diagram illustrating exposing a photopolymer layer to apodization light and grating forming light;

FIG. 8 is a schematic diagram illustrating exposing a photopolymer layer to grating forming light, the photopolymer layer being sandwiched between two layers for inducing apodization by a chemical reaction;

FIG. 9 is a flow chart of a method of manufacturing a pupil-replicating lightguide; and

FIG. 10 is schematic a view of an augmented reality (AR) display of this disclosure having a form factor of a pair of eyeglasses.

### DETAILED DESCRIPTION

While the present teachings are described in conjunction with various embodiments and examples, it is not intended that the present teachings be limited to such embodiments. On the contrary, the present teachings encompass various alternatives and equivalents, as will be appreciated by those of skill in the art. All statements herein reciting principles, aspects, and embodiments of this disclosure, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

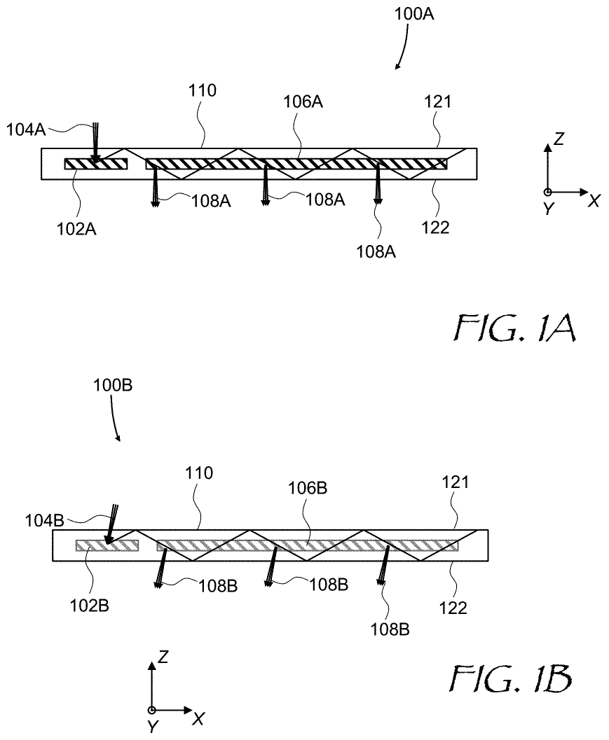

As used herein, the terms “first”, “second”, and so forth are not intended to imply sequential ordering, but rather are intended to distinguish one element from another, unless explicitly stated. Similarly, sequential ordering of method steps does not imply a sequential order of their execution, unless explicitly stated. In FIGS. 1A, 1B, 2, 3F, and FIG. 5, similar reference numerals denote similar elements.

Lightguides are used in optical devices to carry light from one location to another. Pupil-replicating lightguides are used in near-eye displays for providing multiple laterally offset copies of a fan of light beams carrying an image in angular domain for observation by a user of a near-eye display. The multiple offset copies of the beam fan are spread over an eyebox of the display, making observation of the image less dependent on the eye position in the eyebox.

Pupil-replicating lightguides may include diffraction grating couplers for in-coupling and out-coupling image light. Volume Bragg gratings (VBGs) can in-couple and out-couple image light with high efficiency. VBGs however operate in a rather narrow angular range for a given wavelength. To increase overall angular range and color uniformity of the display, multiple pairs of in-coupling and out-coupling VBGs may be provided in a pupil-replicating lightguide. VBGs of different pairs may have optical crosstalk. When the image light is reflected by an out-coupling VBG after being in-coupled by an in-coupling VBG of a different VBGs pair, a ghost image may appear.

In accordance with this disclosure, optical crosstalk and resulting image ghosting and contrast/clarity reduction of a pupil-replicating lightguide based on volume gratings may be suppressed by apodizing the refractive index profile of volume gratings in the direction of thickness of the pupil-replicating lightguide. Such apodization may be achieved e.g. chemically or photochemically.

In accordance with this disclosure, there is provided an optical coupler comprising a plurality of volume gratings in the substrate, each volume grating of the plurality of volume gratings comprising an array of fringes at a grating pitch, the fringes extending along length and thickness dimensions of the substrate. A difference between a refractive index of the fringes and a refractive index of the substrate depends on a depth coordinate along the thickness dimension of the substrate. A dependence of the difference on the depth coordinate comprises a bell-shaped function. The fringes may form an acute angle with the substrate. Different volume gratings of the plurality of volume gratings may overlap in the substrate. The bell-shaped function may include a Gaussian function, for example.

In some embodiments, the bell-shaped function monotonically increases towards a center thickness of the substrate from both sides of the substrate. The bell-shaped functions of different volume gratings of the plurality of volume gratings may have different amplitudes. The grating pitches of different volume gratings of the plurality of volume gratings may be different. Different volume gratings of the plurality of volume gratings may be configured to in-couple light impinging onto the substrate at different angles of incidence, and/or to out-couple light propagating in the substrate at different angles of diffraction. The plurality of volume gratings may include e.g. at least 10 volume gratings having different grating pitches.

In accordance with the present disclosure, there is provided a lightguide comprising a substrate comprising two opposed surfaces running parallel to one another for propagating a light beam by a series of reflections from the surfaces, a plurality of in-coupling volume gratings in the substrate for in-coupling the light beam into the substrate, and a plurality of out-coupling volume gratings in the substrate corresponding to the plurality of in-coupling volume gratings, for out-coupling portions of the light beam along the substrate. Each volume grating of the plurality of in-coupling or out-coupling volume gratings comprises an array of fringes at a grating pitch, the fringes extending along length and thickness dimensions of the substrate. A difference between a refractive index of the fringes and a refractive index of the substrate of at least one of the plurality of in-coupling or out-coupling volume gratings depends on a depth coordinate along the thickness dimension of the substrate. A dependence of the difference on the depth coordinate comprises a bell-shaped function.

The bell-shaped function may monotonically increase towards a center thickness of the substrate from both sides of the substrate. The bell-shaped function may comprise a Gaussian function. The bell-shaped functions of different volume gratings of the plurality of in-coupling and out-coupling volume gratings have different amplitudes. Different volume gratings of the plurality of in-coupling volume gratings may be configured to in-couple the light beam impinging onto the substrate at different angles of incidence, and different volume gratings of the plurality of corresponding out-coupling volume gratings may be configured to out-couple the portions the light beam at different angles of diffraction. Herein, “at least one of the in-coupling or out-coupling volume gratings” may include both the in-coupling and the out-coupling volume gratings.

In accordance with the present disclosure, there is further provided a method of manufacturing a lightguide. The method includes forming, in a substrate comprising two opposed surfaces, a plurality of in-coupling volume gratings for in-coupling a light beam into the substrate, and a plurality of out-coupling volume gratings corresponding to the plurality of in-coupling volume gratings, for out-coupling portions of the light beam along the substrate. Each volume grating of the plurality of in-coupling or out-coupling volume gratings comprises an array of fringes at a grating pitch, the fringes extending along length and thickness dimensions of the substrate. The method further includes apodizing the volume gratings of at least one of the plurality of in-coupling or out-coupling volume gratings such that a difference between a refractive index of the fringes and a refractive index of the substrate of the at least one of the plurality of in-coupling or out-coupling volume gratings depends on a depth coordinate along the thickness dimension of the substrate. A dependence of the difference on the depth coordinate comprises a bell-shaped function with a maximum at a center of the bell-shaped function.

In embodiments where the lightguide comprises a photopolymer layer, the forming may include exposing the photopolymer layer to grating forming light for forming the fringes, and the apodizing may include exposing at least one surface of the photopolymer layer to apodization light for reducing the difference proximate the at least one surface. The forming may be performed concurrently with the apodizing, before, and/or after the apodizing.

Examples of lightguides with apodized volume gratings will now be presented. Referring first to FIG. 1A, a pupil-replicating lightguide 100A includes a substrate 110 and an in-coupling volume grating 102A in the substrate 110 for in-coupling image light 104A into the pupil-replicating lightguide 100A, and an out-coupling volume grating 106A in the substrate 110 for out-coupling portions 108A of the image light 104A along a length direction of the pupil-replicating lightguide 100A (X-direction in FIG. 1A). The image light 104A propagates in the substrate by series of reflections from opposed top 121 and bottom 122 surfaces of the substrate 110. The image light 104A carries a portion of an image in angular domain, corresponding to a narrow cone of rays oriented approximately perpendicular to the pupil-replicating lightguide 100A, as shown in FIG. 1A. In this example, the in-coupling volume grating 102A and the out-coupling volume grating 106A have a same pitch, such that the out-coupled portions 108A retain the beam angles of the impinging image light 104A.

Referring to FIG. 1B, a pupil-replicating lightguide 100B is similar to the pupil-replicating lightguide 100A of FIG. 1A. The pupil-replicating lightguide 100B of FIG. 1B includes an in-coupling volume grating 102B in the substrate 110 for in-coupling image light 104B and an out-coupling volume grating 106B in the substrate 110 for out-coupling portions 108B of the image light 104A along a length direction of the pupil-replicating lightguide 100B (X-direction in FIG. 1B). The image light 104B propagates in the substrate by series of reflections from opposed top 121 and bottom 122 surfaces of the substrate 110. The image light 104B carries a different portion of the image in angular domain, corresponding to a narrow cone of rays oriented at an acute, i.e. non-perpendicular, angle to the pupil-replicating lightguide 100B. The in-coupling volume grating 102B and the out-coupling volume grating 106B have a same pitch, such that the out-coupled portions 108B retain the beam angles of the impinging image light 104B.

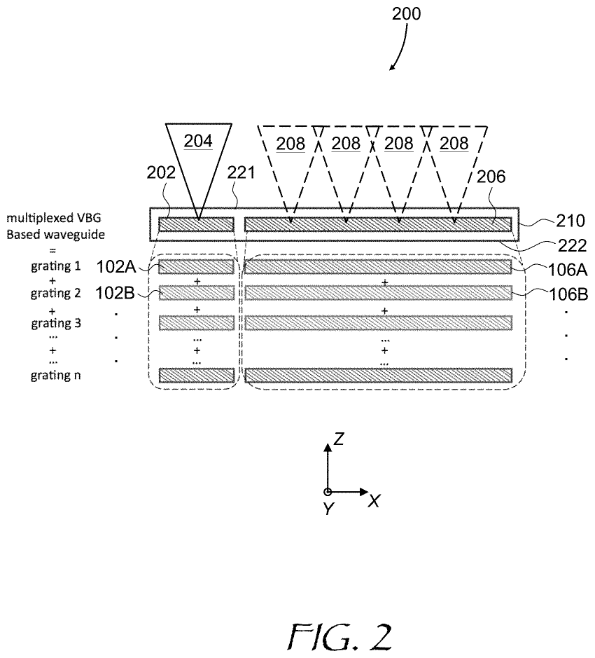

Referring now to FIG. 2, a pupil-replicating lightguide 200 includes an in-coupler 202 in a substrate 210. The in-coupler 202 includes a plurality of multiplexed in-coupling volume gratings, e.g. the in-coupling volume grating 102A of FIG. 1A, the in-coupling volume grating 102b of FIG. 1B, and other in-coupling volume gratings of different pitches or periods, superimposed in the pupil-replicating lightguide 200. The volume gratings may occupy a same volume area of the substrate 210, and/or may be disposed at different depths in the substrate 210. Different volume gratings of the plurality of in-coupling volume gratings are configured to in-couple the image light 204 impinging onto the substrate 210 at different angles of incidence. Together, the in-coupling volume gratings in-couple image light 204 covering an entire field of view (FOV) of an image in angular domain to be carried by the pupil-replicating lightguide 200 and displayed to a user. The in-coupled image light 204 propagates in the substrate by series of reflections from opposed top 221 and bottom 222 surfaces of the substrate 210.

An out-coupler 206 in the substrate 210 includes a plurality of multiplexed out-coupling volume gratings, e.g. the out-coupling volume grating 106A of FIG. 1A, the out-coupling volume grating 106b of FIG. 1B, and other out-coupling volume gratings, superimposed in the pupil-replicating lightguide 200. Different volume gratings of the plurality of out-coupling volume gratings are configured to out-couple the image light 204 propagating in the substrate 210 at different angles of diffraction. Together, the out-coupling volume gratings out-couple portions 208 of the image light 204 covering the entire FOV. Different portions of the FOV are being conveyed by the pupil-replicating lightguide 200 by different matching pairs of volume gratings. It is further noted that one out-coupling volume grating per an in-coupling volume grating is only meant as an example. Two or more out-coupling volume gratings may be provided per each in-coupling volume grating. Various lightguide types, including straight lightguides, curved lightguides, 1D/2D lightguides, etc., may be configured to have matching volume grating pairs. Herein and throughout the rest of the specification, the volume gratings may include VBGs, polarization volume holograms (PVH), etc.

For the pupil-replicating lightguide 200 to operate as intended, the image light 204 portions should be redirected only by volume gratings of a same in-coupling and out-coupling volume grating pair, corresponding to a same particular FOV portion. If a portion of the image light 204 is in-coupled into the pupil-replicating lightguide 200 by a volume grating from one in-coupling/out-coupling volume grating pair, and is out-coupled by a volume grating from another in-coupling/out-coupling volume grating pair, an offset image (ghosting) will result.

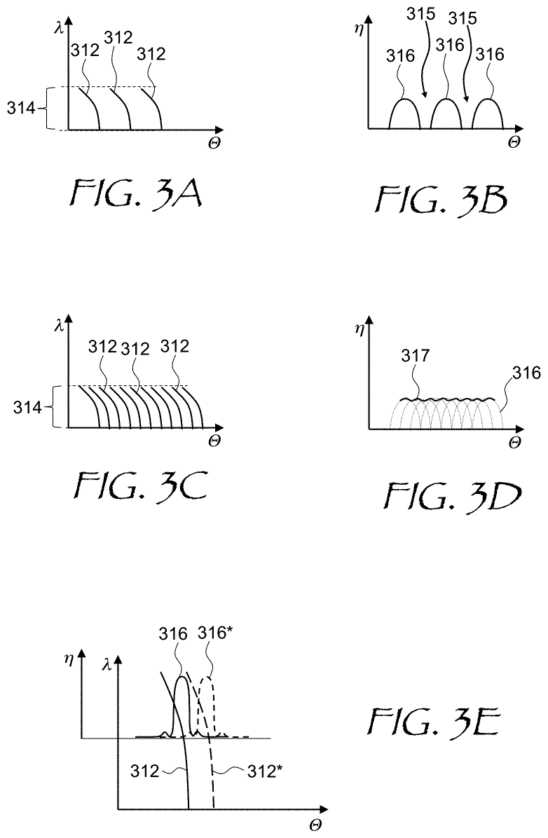

Origins of the optical crosstalk between different volume grating pairs are further illustrated in FIGS. 3A to 3F. Referring first to FIGS. 3A and 3B, a grating coupler may include a plurality of volume gratings having angular dependencies 312 of diffraction wavelength λ (FIG. 3A) offset relative to one another along an axis of the diffraction angle Θ, due to the volume gratings having different pitches. The angular dependencies 312 are shown for a bandwidth 314 of illuminating light. The angular dependencies 312 are sparsely spaced in the diffraction angle Θ in this example, which results in gaps 315 between plots 316 of angular dependence of diffraction efficiency η of the individual volume gratings (FIG. 3B). When such grating coupler is used in a pupil-replicating lightguide, the gaps 315 will result in FOV gaps in the displayed image.

The gaps 315 may be avoided by providing tighter spacing between the pitch values of the volume gratings multiplexed in a grating coupler, which will cause the angular dependencies 312 to be spaced closer together. Referring to FIGS. 3C and 3D, the angular dependencies 312 are densely spaced in angle (FIG. 3C), eliminating gaps between angular efficiency plots 316. The angular efficiency plots 316 “coalesce” in a continuous, gap-free angular efficiency curve 317 (FIG. 3D). The grating coupler with the densely spaced (in angular domain) volume gratings will result in a continuous, gap-free FOV.

Too close a spacing of the volume grating pitches and resulting gap-free FOV may result in optical crosstalk, which manifests itself in image contrast loss and/or the appearance of ghost images. Referring to FIG. 3E for example, angular dependencies 312, 312* of first and second diffraction wavelengths of neighboring volume gratings (i.e. neighboring in pitch) are shown superimposed with corresponding magnified first and second diffraction efficiency curves 316, 316* for these volume gratings. When the first and second diffraction efficiency curves 316, 316* are disposed too close to each other, crosstalk may result causing the light to be diffracted by a “wrong” volume grating.

The latter point is illustrated in FIG. 3F showing a pupil-replicating lightguide 300. A light beam 304 impinges onto an in-coupler comprising a plurality of in-coupling volume gratings, including a first in-coupling volume grating 302, in a substrate 310. The other in-coupling volume gratings are not shown for clarity. The in-coupling volume grating 302 redirects the light beam 304 to propagate in the pupil-replicating lightguide 300 towards an out-coupler comprising a plurality of out-coupling volume gratings in the substrate 310. The out-coupler includes a first out-coupling volume grating 306 matching the first in-coupling volume grating 302 and having the first angular dependence 316 (FIG. 3E) of diffraction efficiency η, and a second out-coupling volume grating 306* (FIG. 3F) having the second angular dependence 316* of diffraction efficiency η. Only two out-coupling volume gratings are shown in FIG. 3F for clarity. The fringes of the in-coupling and out-coupling volume gratings may form an acute angle with the substrate 310, as shown in FIG. 3F.

In operation, a first output light beam 308 diffracts from a “correct”, i.e. the matching first out-coupling volume grating 306. A second output light beam 308* diffracts from a “wrong” volume grating, i.e. the second out-coupling volume grating 306*. The second output light beam 308* propagates in a different direction than the first output light beam 308 because the second out-coupling volume grating has a slightly different pitch than the first out-coupling volume grating. The second output light beam 308* corresponds to an incorrect image, i.e. a ghost image.

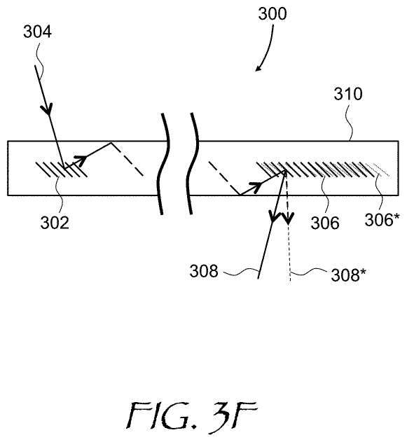

The origins of the “incorrect” reflection are further illustrated in FIG. 4A, where reflectivity R of the two adjacent volume gratings is plotted against an angle of reflective diffraction θ in degrees. The reflectivity R corresponds to the diffraction efficiency η in a reflective volume grating configuration. For each volume grating, the reflectivity dependence on the angle of diffraction R(θ) includes a central peak 401A and sidelobes 402A on both sides of the central peak 401A. It is seen that the sidelobes 402A of one volume grating may overlap with an area of the central peak 401A of the other volume grating. The overlap means that, while most of the image light is reflected by the central reflectivity peak 401A of the “correct” volume grating as the first output light beam 308 (FIG. 3F), a small portion of the image light may be reflected by a sidelobe of the “incorrect” volume grating producing the second output light beam 308*. It is such diffraction off the “incorrect” output volume gratings that causes the contrast loss/image ghosting to occur. Therefore, the sidelobes 402A of the reflectivity dependences R(θ) are undesirable, because they degrade the image quality.

In accordance with the present disclosure, sidelobes of an angular reflectivity spectrum of a volume grating and associated image ghosting may be suppressed by apodizing the volume grating in a direction of thickness of the substrate hosting the volume grating, i.e. generally in a direction perpendicular to a pitch direction of the array of fringes of the volume grating. In FIG. 4B, a reflectivity R of apodized volume gratings from two adjacent volume grating pairs is plotted against an angle of reflective diffraction θ in degrees. Only central peaks 401B are present, with the sidelobes significantly reduced. Accordingly, the image light may not reflect from an “incorrect” volume grating of a volume grating pair, resulting in a ghost-free image. At least, image ghosts may be considerably suppressed. The plots depicted in FIGS. 4A and 4B are based on physical optics simulations of the grating structures performed using rigorous coupled wave analysis (RCWA). It is noted that volume gratings in grating couplers considered herein may also operate in transmission instead of reflection, and may also undergo image ghosting.

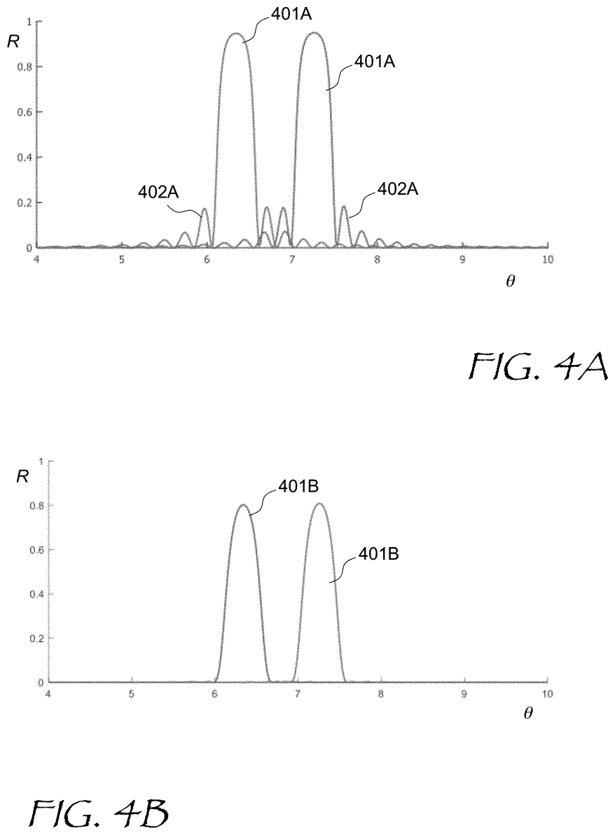

Referring now to FIG. 5, an optical coupler 500 may be a part of the pupil-replicating waveguide 100A of FIG. 1A, the pupil-replicating waveguide 100B of FIG. 1B, the pupil-replicating waveguide 200 of FIG. 2, and the pupil-replicating waveguide 300 of FIG. 3F. The optical coupler 500 includes a substrate 510 having opposed first 521 and second 522 surfaces parallel to XY plane. The direction of thickness t of the substrate is Z-direction in FIG. 5. The substrate 510 may, but does not have to be, flat; in a curved substrate variant, the first 521 and second 522 surfaces may run parallel to one another. The optical coupler 500 represents an in-coupler for in-coupling an impinging light beam, as well as an out-coupler for out-coupling portions of the light beam at different locations along the substrate 510. The optical coupler 500 may include a plurality of volume gratings 520, e.g. at least 10, 20, 50, 100, or more volume gratings having different grating pitches.

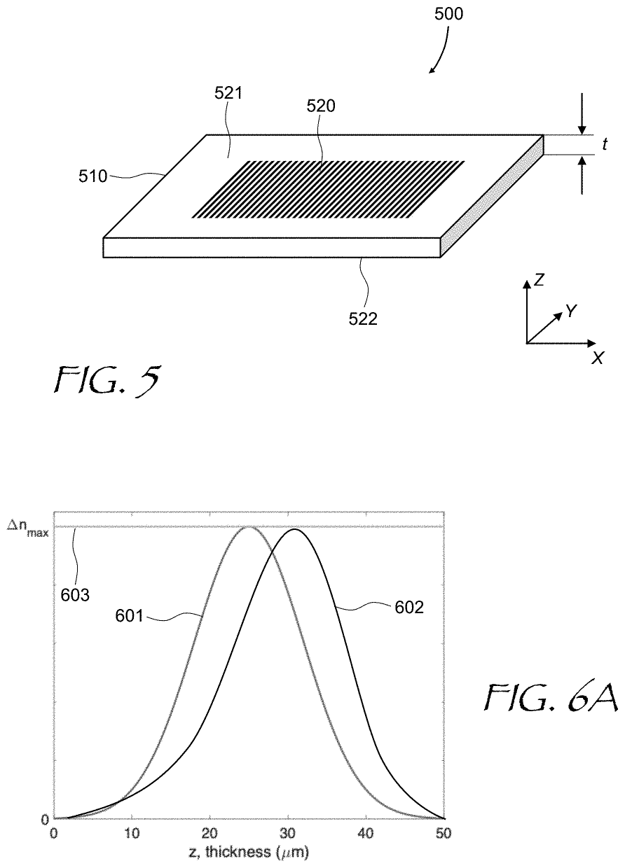

Turning to FIG. 6A, a profile 601 of a refractive index contrast, that is, a difference between a refractive index of the volume grating fringes and a refractive index of the substrate 510, is plotted as a function of the thickness coordinate Z. The first profile 601 is described by a Gaussian function in this example. Non-Gaussian function may also be used. More generally, the refractive index contrast variation of each volume grating of the plurality of volume gratings may have a bell-shaped or a similar function. The bell-shaped function may have the tip of the bell inside the substrate 510 and the lip of the bell at outer surfaces of the substrate 510. In other words, the bell-shaped function monotonically increases towards a center thickness of the substrate 510 from both outer surfaces (i.e. top and bottom surfaces in FIG. 5) of the substrate 510. The maximum may, but does not have to, be disposed proximate a middle of the thickness t of the substrate 510. For example, in some embodiments the bell-shaped profile may be skewed toward one side, such as a second profile 602. The fringes of the grating couplers disposed in the substrate 510 may form an acute angle with the substrate 510, while their refractive index contrast varies according to the first 601 or second 602 profiles. A uniform profile 603, i.e. that of a non-apodized grating, is also shown for a comparison. Different volume gratings may spatially overlap in the substrate 510 while having a same or a different z-profile of the refractive index contrast.

The latter point—different z-profiles of the refractive index contrast—is illustrated in FIG. 6B, where the refractive index contrast amplitude of volume gratings of the optical coupler 500 of FIG. 5 is plotted as a function of volume grating pitch, for a coupler having the apodization of different volume gratings independently optimized using a numerical simulation. The volume gratings of the optical coupler 500 have different pitches, and the bell-shaped functions of different volume gratings of the plurality of volume gratings of the optical coupler 500 have different amplitudes for an optimal performance of the coupler 500.

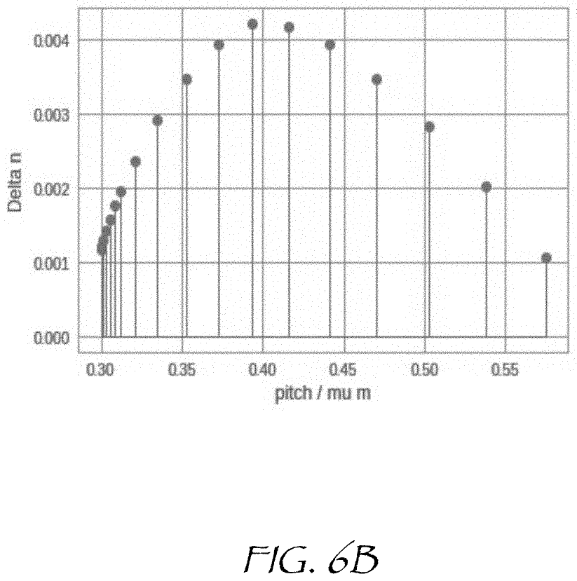

Refractive index contrast apodization of volume grating-based grating couplers may be achieved by employing a variety of methods, including photochemical and chemical apodization methods. FIG. 7 illustrates a photochemical method. A photopolymer (PP) layer 710, which may be supported by an optional substrate (not shown for clarity), is disposed in XY plane. The PP layer 710 is exposed to a grating forming light 704 formed by interference of first 711 and second 712 coherent light beams at a wavelength λ_{grating} illuminating opposed top 721 and bottom 722 surfaces, respectively, of the PP layer 710 with oblique coherent first 711 and second 712 beams of light, forming an interference pattern in the PP layer 710, which corresponds to the fringe pattern of the volume grating to be formed. The PP material changes its refractive index in areas of high intensity of the interference pattern formed by the first 711 and second 712 beams of the grating forming light 704, while in areas of low intensity of the interference pattern the refractive index remains unchanged, or changes very little. The grating forming light 704 is typically monochromatic. The PP layer 710 may be subjected to a plurality of exposures of the grating forming light 704 at different angles of incidence and/or different wavelengths. The PP layer 710 may undergo tens or even hundreds of such exposures.

The grating apodization may be achieved by illuminating at least one of the top 721 or bottom 722 surfaces of the PP layer 710 with apodization light beams 702 at a wavelength λ_{apodization}. The apodization light beams 702 may be oriented perpendicular to the PP layer, e.g. along Z-direction, for normal incidence onto the top 721 and/or bottom 722 surfaces of the PP layer 710. The wavelength or wavelengths λ_{apodization} of the apodization light may be selected such that a major portion of the apodization light is absorbed before reaching the middle of the PP layer 710, to provide the sought-for profile of the refractive index contrast. The illumination of the PP layer 710 with the apodization light beams 702 facilitates the reduction of the refractive index contrast near the top 721 and bottom 722 surfaces of the PP layer 710 to a greater degree than at a center, which causes the grating's refractive index profile to be apodized. Depending on the specifics of photochemical processes used, the apodization illumination may precede, be concurrent with, or follow the grating forming illumination. The degree of apodization depends on the absorption coefficient at the apodization wavelength λ_{apodization} and the thickness (along Z-dimension) of the PP layer 710.

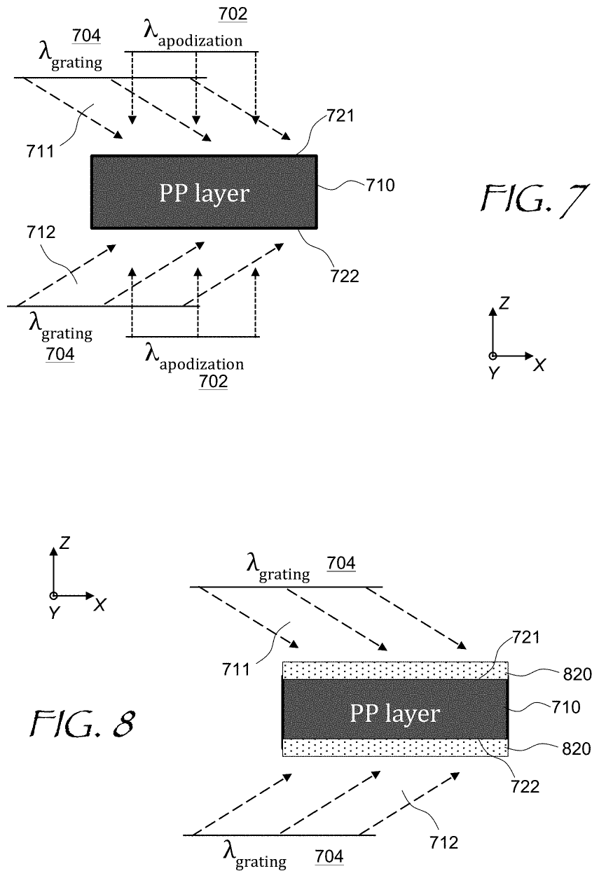

In some embodiments, the apodization may be induced chemically, or the chemical apodization may complement the photoinduced apodization described above with reference to FIG. 7. A chemical apodization process is illustrated in FIG. 8, where chemically active layers 820, also termed inhibitor layers, are added to the top 721 and/or bottom 722 surfaces of the PP layer 710. At least one inhibitor layer 820 may be provided. The function of the inhibitor layer(s) 820 is to controllably suppress the photopolymerization process initiated by the grating forming light 704. The apodization may be performed such that the refractive index contrast variation of each volume grating may be substantially the same, e.g. may differ within 5% of one another.

In the grating apodization configurations presented above with reference to FIGS. 7 and 8, different volume gratings of the plurality of volume gratings formed in the PP layer 710 may be disposed at different depths of the PP layer 710, and may have different height along the Z-coordinate, to achieve different apodization levels and/or different grating diffraction efficiency. At least 10 volume gratings having different pitches may be provided. In some embodiments, at least 100 volume gratings are provided.

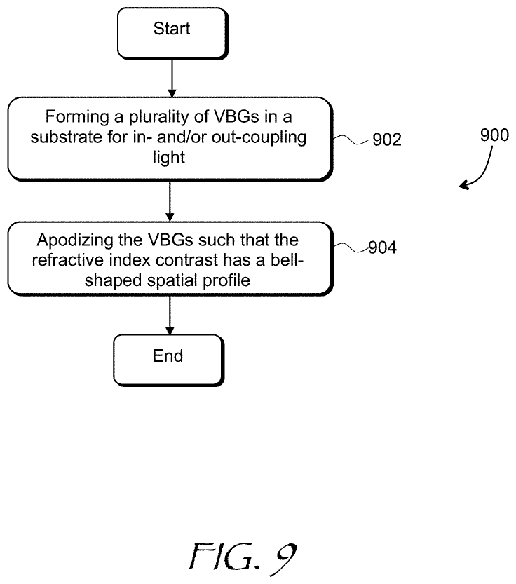

Referring now to FIG. 9, a method 900 for manufacturing a lightguide such as the lightguide 200 of FIG. 2, comprising in-couples and out-couplers, for example the coupler 500 of FIG. 5, includes forming (FIG. 9; 902), in a substrate comprising two opposed surfaces, e.g. the substrate 210 of the lightguide 200 of FIG. 2, a plurality of in-coupling volume gratings for in-coupling a light beam, e.g. the light beam 204 into the substrate 210, and/or a plurality of out-coupling volume gratings corresponding to the plurality of in-coupling volume gratings, for out-coupling portions 208 of the light beam 204 along the substrate 210. Each volume grating of the plurality of in-coupling or out-coupling volume gratings includes an array of fringes at a grating pitch. The fringes extend along length dimension (X-dimension in FIG. 2) and thickness dimension (Z-dimension in FIG. 2) of the substrate 210.

The volume gratings of at least one of the plurality of in-coupling or out-coupling volume gratings are apodized (FIG. 9; 904) such that a difference between a local refractive index of the fringes and a local refractive index of the substrate, i.e. the refractive index contrast, of the at least one of the plurality of in-coupling or out-coupling volume gratings depends on a depth coordinate (Z-coordinate in FIGS. 2, 5, 7, and 8), i.e. the coordinate along the thickness dimension of the substrate. As explained above with reference to FIGS. 5 and 6A, the dependence of the refractive index contrast on the depth coordinate can be expressed by a bell-shaped function (e.g. 601, 602 in FIG. 6A) with a maximum at or near a center of the bell-shaped function.

The grating-carrying region of the lightguide may include a photopolymer layer. The in-coupling and/or out-coupling gratings may be formed in the photopolymer layer by exposing the photopolymer layer to an interference pattern corresponding to the desired grating, as has been explained above with reference to FIGS. 5, 7, and 8. In such embodiments, the apodizing may be performed by exposing at least one surface of the photopolymer layer to apodization light for reducing the refractive index contrast proximate the that surface or surfaces, as shown in FIG. 7, for example.

The grating forming 902 may be performed concurrently with the apodizing 904, before the apodizing 904, and/or after the apodizing. The apodizing 904 may be performed photochemically as explained above with reference to FIG. 7, and/or chemically as explained above with reference to FIG. 8.

The grating forming 902 may include a plurality of photo exposure steps. A single grating, or several gratings, may be exposed during a single step. The grating forming steps are repeated until all the required gratings of a coupler are formed. The gratings may be formed superimposed, i.e. different volume gratings with different spatial pitch, optimized for operation in different angular ranges, may overlap spatially within the photopolymer layer. Different gratings may be formed at different depth levels. Furthermore, some of the gratings may be wider than the others.

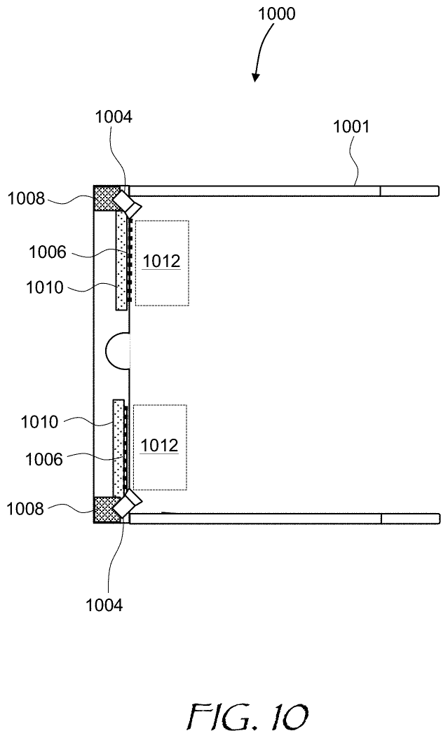

Turning to FIG. 10, an augmented reality (AR) near-eye display 1000 includes a frame 1001 having a form factor of a pair of eyeglasses. The frame 1001 supports, for each eye: a projector 1008, a pupil-replicating lightguide 1010 optically coupled to the projector 1008, an eye-tracking camera 1004, and plurality of illuminators 1006. The pupil-replicating lightguide 1010 may include any of the in- and/or out-couplers disclosed herein, the in- and/or out-couplers comprising Z-apodized volume gratings disclosed herein. The illuminators 1006 may be supported by the pupil-replicating lightguide 1010 for illuminating an eyebox 1012. The projector 1008 provides a fan of light beams carrying an image in angular domain to be projected into a user's eye. The pupil-replicating lightguide 1010 receives the fan of light beams and provides multiple laterally offset parallel copies of each beam of the fan of light beams, thereby extending the projected image over the eyebox 1012.

The purpose of the eye-tracking cameras 1004 is to determine position and/or orientation of both eyes of the user. Once the position and orientation of the user's eyes are known, a gaze convergence distance and direction may be determined. The imagery displayed by the projectors 1008 may be adjusted dynamically to account for the user's gaze, for a better fidelity of immersion of the user into the displayed augmented reality scenery, and/or to provide specific functions of interaction with the augmented reality.

In operation, the illuminators 1006 illuminate the eyes at the corresponding eyeboxes 1012, to enable the eye-tracking cameras to obtain the images of the eyes, as well as to provide reference reflections i.e. glints. The glints may function as reference points in the captured eye image, facilitating the eye gazing direction determination by determining position of the eye pupil images relative to the glints images. To avoid distracting the user with illuminating light, the latter may be made invisible to the user. For example, infrared light may be used to illuminate the eyeboxes 1012.

Embodiments of the present disclosure may include, or be implemented in conjunction with, an artificial reality system. An artificial reality system adjusts sensory information about outside world obtained through the senses such as visual information, audio, touch (somatosensation) information, acceleration, balance, etc., in some manner before presentation to a user. By way of non-limiting examples, artificial reality may include virtual reality (VR), augmented reality (AR), mixed reality (MR), hybrid reality, or some combination and/or derivatives thereof. Artificial reality content may include entirely generated content or generated content combined with captured (e.g., real-world) content. The artificial reality content may include video, audio, somatic or haptic feedback, or some combination thereof. Any of this content may be presented in a single channel or in multiple channels, such as in a stereo video that produces a three-dimensional effect to the viewer.

Furthermore, in some embodiments, artificial reality may also be associated with applications, products, accessories, services, or some combination thereof, that are used to, for example, create content in artificial reality and/or are otherwise used in (e.g., perform activities in) artificial reality. The artificial reality system that provides the artificial reality content may be implemented on various platforms, including a wearable display such as an HMD connected to a host computer system, a standalone HMD, a near-eye display having a form factor of eyeglasses, a mobile device or computing system, or any other hardware platform capable of providing artificial reality content to one or more viewers.

The present disclosure is not to be limited in scope by the specific embodiments described herein. Indeed, other various embodiments and modifications, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An optical coupler comprising:
a substrate; and
a plurality of volume gratings in the substrate, each volume grating of the plurality of volume gratings comprising an array of fringes at a grating pitch, the fringes extending along length and thickness dimensions of the substrate;
wherein a difference between a refractive index of the fringes and a refractive index of the substrate depends on a depth coordinate along the thickness dimension of the substrate, wherein a dependence of the difference on the depth coordinate comprises a bell-shaped function.

2. The optical coupler of claim 1, wherein the bell-shaped function monotonically increases towards a center thickness of the substrate from both sides of the substrate.

3. The optical coupler of claim 1, wherein the bell-shaped function comprises a Gaussian function.

4. The optical coupler of claim 1, wherein the fringes form an acute angle with the substrate.

5. The optical coupler of claim 1, wherein different volume gratings of the plurality of volume gratings overlap in the substrate.

6. The optical coupler of claim 1, wherein the bell-shaped functions of different volume gratings of the plurality of volume gratings have different amplitudes.

7. The optical coupler of claim 1, wherein the grating pitches of different volume gratings of the plurality of volume gratings are different.

8. The optical coupler of claim 7, wherein different volume gratings of the plurality of volume gratings are configured to in-couple light impinging onto the substrate at different angles of incidence.

9. The optical coupler of claim 7, wherein different volume gratings of the plurality of volume gratings are configured to out-couple light propagating in the substrate at different angles of diffraction.

10. The optical coupler of claim 7, wherein the plurality of volume gratings comprises at least 10 volume gratings having different grating pitches.

11. A lightguide comprising:
a substrate comprising two opposed surfaces running parallel to one another for propagating a light beam by a series of reflections therefrom;
a plurality of in-coupling volume gratings in the substrate for in-coupling the light beam into the substrate; and
a plurality of out-coupling volume gratings in the substrate corresponding to the plurality of in-coupling volume gratings, for out-coupling portions of the light beam along the substrate;
wherein each volume grating of the plurality of in-coupling or out-coupling volume gratings comprises an array of fringes at a grating pitch, the fringes extending along length and thickness dimensions of the substrate;
wherein a difference between a refractive index of the fringes and a refractive index of the substrate of at least one of the plurality of in-coupling or out-coupling volume gratings depends on a depth coordinate along the thickness dimension of the substrate, wherein a dependence of the difference on the depth coordinate comprises a bell-shaped function.

12. The lightguide of claim 11, wherein the bell-shaped function monotonically increases towards a center thickness of the substrate from both sides of the substrate.

13. The lightguide of claim 11, wherein the bell-shaped function comprises a Gaussian function.

14. The lightguide of claim 11, wherein the bell-shaped functions of different volume gratings of the plurality of in-coupling and out-coupling volume gratings have different amplitudes.

15. The lightguide of claim 11, wherein:
different volume gratings of the plurality of in-coupling volume gratings are configured to in-couple the light beam impinging onto the substrate at different angles of incidence; and
different volume gratings of the plurality of corresponding out-coupling volume gratings are configured to out-couple the portions the light beam at different angles of diffraction.

16. The lightguide of claim 11, wherein the at least one of the in-coupling or out-coupling volume gratings comprises both the in-coupling and the out-coupling volume gratings.

17. A method of manufacturing a lightguide, the method comprising:
forming, in a substrate comprising two opposed surfaces, a plurality of in-coupling volume gratings for in-coupling a light beam into the substrate, and a plurality of out-coupling volume gratings corresponding to the plurality of in-coupling volume gratings, for out-coupling portions of the light beam along the substrate, wherein each volume grating of the plurality of in-coupling or out-coupling volume gratings comprises an array of fringes at a grating pitch, the fringes extending along length and thickness dimensions of the substrate; and
apodizing the volume gratings of at least one of the plurality of in-coupling or out-coupling volume gratings such that a difference between a refractive index of the fringes and a refractive index of the substrate of the at least one of the plurality of in-coupling or out-coupling volume gratings depends on a depth coordinate along the thickness dimension of the substrate, wherein a dependence of the difference on the depth coordinate comprises a bell-shaped function with a maximum at a center of the bell-shaped function.

18. The method of claim 17, wherein the lightguide comprises a photopolymer layer, and wherein:
the forming comprises exposing the photopolymer layer to grating forming light for forming the fringes; and
the apodizing comprises exposing at least one surface of the photopolymer layer to apodization light for reducing the difference proximate the at least one surface.

19. The method of claim 17, wherein the forming is performed concurrently with the apodizing.

20. The method of claim 17, wherein the forming is performed before or after the apodizing.
